(19) United States
(12) Patent Application Publication
(10) Pub. No.: US 2018/0090467 A1
(43) Pub. Date: Mar. 29, 2018

(54) PACKAGE WITH THERMAL COUPLING

(71) Applicant: Intel Corporation, Santa Clara, CA (US)

(72) Inventors: Hyoung II Kim, Folsom, CA (US); Saeed S. Shojaie, Folsom, CA (US)

(21) Appl. No.: 15/277,581

(22) Filed: Sep. 27, 2016

(51) Int. Cl. H01L 25/065; H01L 25/00

(52) U.S. Cl. CPC H01L 25/0657; H01L 25/50; H01L 2225/06589; H01L 2225/06555; H01L 2225/06586; H01L 2225/0651

(57) ABSTRACT

Embodiments herein relate to thermal coupling using through mold vias (TMV). Embodiments may include a substrate having a first side and a second side opposite the first side, a processor having a first side and the second side, the first side of the processor coupled to the first side of the substrate, one or more solder balls where the first side of the one or more solder balls are thermally coupled to the second side of the processor and where the solder balls are embedded in one or more TMVs in a molding extending from a first side of the molding to a second side of the molding opposite the first side of the molding. Other embodiments may be described and/or claimed.

### FIELD

Embodiments of the present disclosure generally relate to the field of package assemblies, and in particular package assemblies having high thermal conductivity.

### BACKGROUND

Continued reduction in end product size of mobile electronic devices such as smart phones and ultrabooks is a driving force for the development of reduced size system in package (SIP) components. With the reduced size also frequently comes increased component density with an increased thermal output from the SIP.

### BRIEF DESCRIPTION OF THE DRAWINGS

FIGS. 1-8 illustrate an example of a package assembly at various stages of a manufacturing process, in accordance with embodiments.

FIGS. 9-12 illustrate an example of a package assembly at various stages of a manufacturing process, in accordance with embodiments.

FIG. 13 illustrates an example of a process for manufacturing a package assembly, in accordance with embodiments.

FIG. 14 illustrates an example of a process for manufacturing a package assembly, in accordance with embodiments.

FIG. 15 schematically illustrates a computing device, in accordance with embodiments.

### DETAILED DESCRIPTION

Embodiments of the present disclosure may generally relate to improved thermal properties within an SIP to channel thermal energy from heat-producing components away from components that may have more narrow operational thermal tolerances. In embodiments, this may include conduction of thermal energy from an application specific integrated circuit (ASIC) to a printed circuit board (PCB) and/or improved thermal convection from the ASIC to the surrounding environment by using through mold conducting solder balls and thermal interface material (TIM). Embodiments may include the use of through mold vias (TMVs) filled with a substance such as a solder to thermally conduct heat from the heat source, such as from a processor or application specific integrated circuit (ASIC), to a heat pad.

In addition, higher-quality thermally insulating material, such as glass, may be introduced between temperature sensitive devices, for example dynamic random-access memory (DRAM) or NAND, and the heat source, for example ASIC, to minimize heat conduction toward the temperature sensitive devices.

The use of heat spreaders and/or thermal vias in this disclosure, and as illustrated by various embodiments described herein, may have advantages over legacy implementations. For example, embodiments described herein may overcome bulkier legacy packages using thermal slugs by producing packages that may be more space efficient. For example, space around a processor in legacy packages is now not needed to create a thermal path to a substrate and then through solder balls to a PCB. The described embodiments may reduce or eliminate the risk of delamination within a system in package (SIP) of a heat spreader to the surrounding mold compound.

In embodiments, SIPs may be miniaturized with additional components, including heat generating components, integrated into the SIP. For example, miniaturized solid state drives (SSD) may be manufactured in SIP form. For example, dimensions for SIP systems may be 16×20×1.65 or 11.5×13×1.2 millimeters (mm) and contain a large number of components, such as over 150, to fit within a small space. In embodiments, these components may include ASIC, dynamic random access memory (DRAM), not-AND (NAND) gate memory, or 3D XPoint™ memory, power system, crystal, and the like, all of which may be co-packaged within a SIP. Some of these components may be within hundreds of microns of each other. In embodiments, these components may be die stacks.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

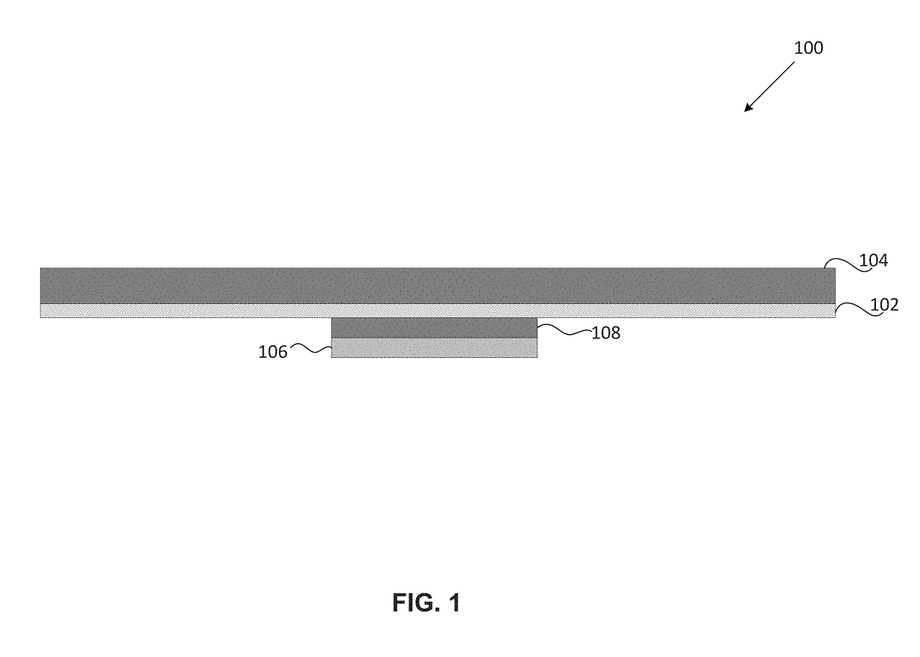

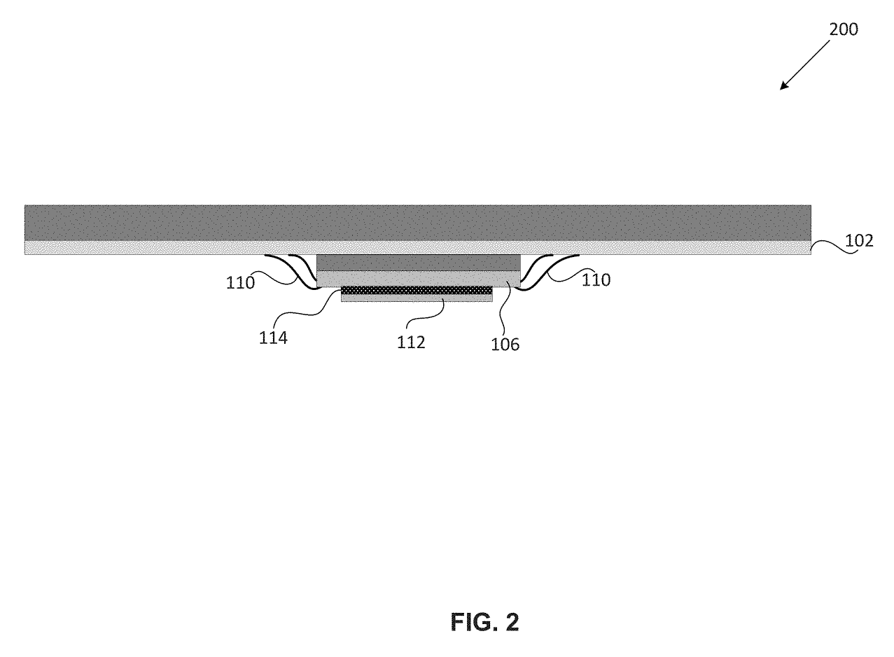

FIGS. 1-8 illustrate an example of a package assembly at various stages of a manufacturing process, in accordance with embodiments. In embodiments, one or more elements may be introduced in an earlier figure, for example FIG. 1, and then assumed to carry over to later Figures such as FIG. 2. Therefore, each and every element of the package assembly may not be labeled in each and every stage of FIGS. 1-8 for the sake of clarity and the ease of understanding.

Specifically, FIG. 1 shows a package assembly embodiment 100 that includes a substrate layer 102 that may be coupled to a carrier layer 104. In embodiments, the substrate 102 may be a redistribution layer (RDL). In embodiments, a processor 106 may be attached to a surface of the substrate 102. In embodiments the processor 106 may be a collection of processors, one or more ASICs, or some other heat-generating component. In embodiments, the processor 106 may be coupled to the substrate 102 by an adhesive film 108.

FIG. 2 illustrates a package assembly embodiment 200 that shows one or more electrical connections 110 between the processor 106 and the substrate 102. In embodiments, the processor 106 may be implemented as a flip chip and not require wire bonded electrical connections 110. A heat spreader 112 may be coupled with the processor 106. In embodiments, the heat spreader may be made of a material that readily conducts thermal energy, for example a copper slug. A thermal interface material (TIM), having the characteristics of good adhesion and thermal conductivity may be placed between the heat slug 112 and the processor 106. In embodiments, the TIM 114 will allow the heat from processor 106 to readily flow to the heat spreader 112.

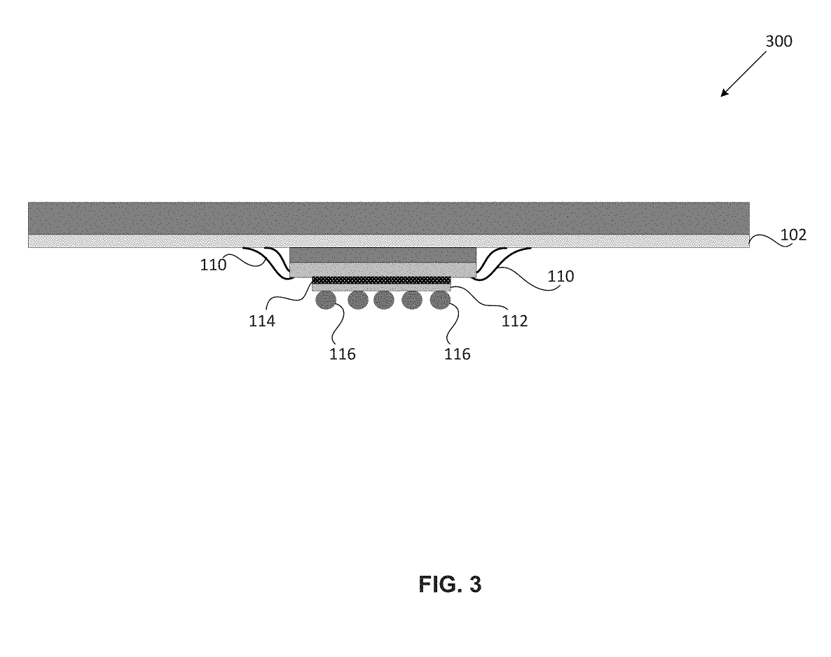

FIG. 3 illustrates a package assembly 300 that shows one or more solder balls 116 that are coupled with the heat spreader 112. In embodiments, the solder balls may be made of A-10 alloy, or some other heat conducting substance.

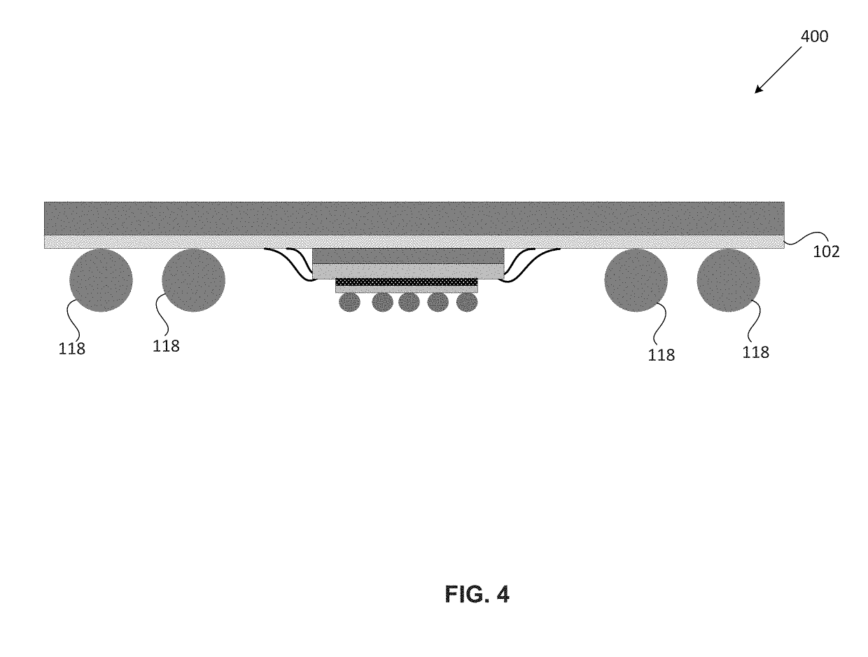

FIG. 4 illustrates a package assembly 400 that shows one or more solder balls 118 coupled to the substrate 102. In embodiments, the one or more solder balls 118 may provide electrical connections between the substrate 102, for example as an RDL, and a PCB (not shown).

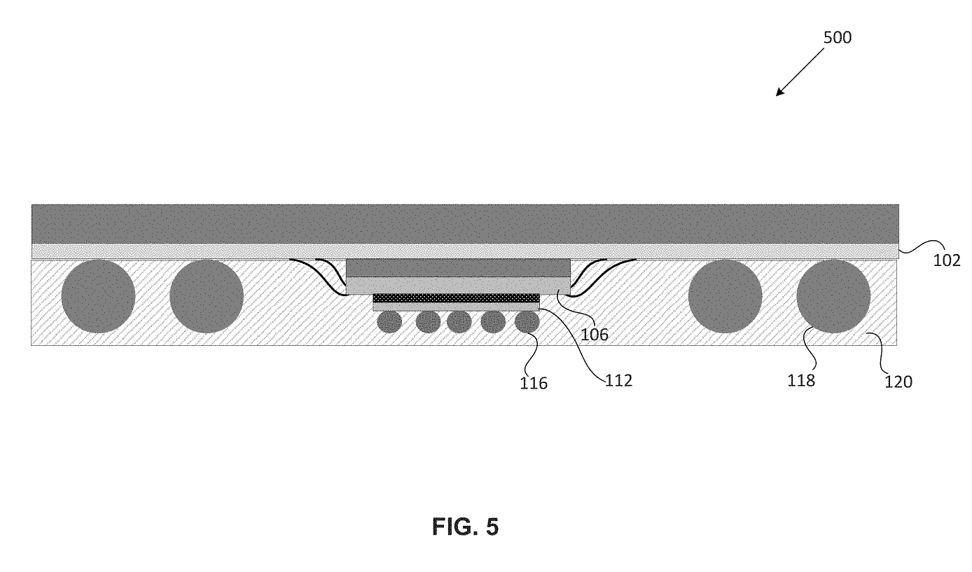

FIG. 5 illustrates a package assembly 500 that shows a molding compound 120 surrounding part of the package assembly. In embodiments, the molding compound 120 is adjacent to the substrate 102 and encompasses solder balls 116, 118 heat spreader 112 and processor 106.

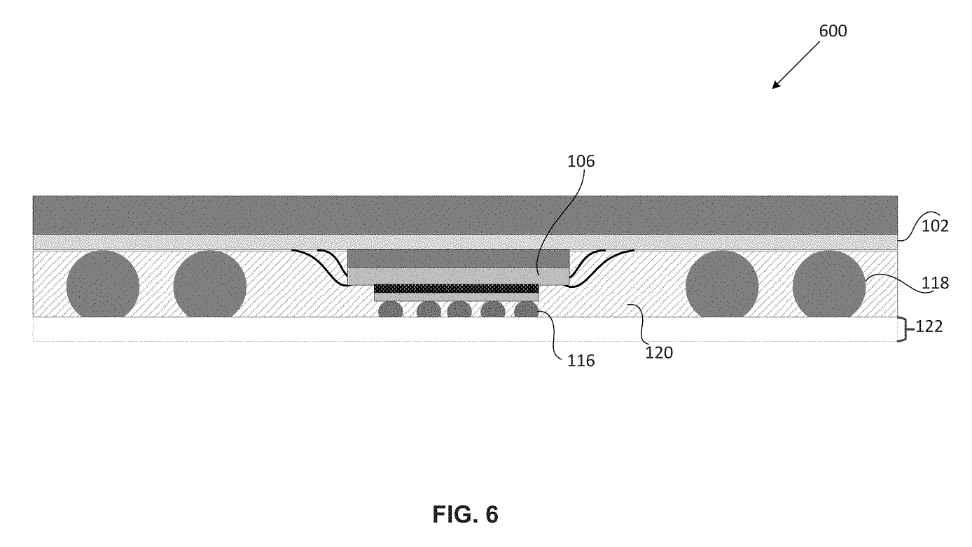

FIG. 6 illustrates a package assembly 600 that shows part of the molding compound 122 has been ground away to expose a portion of solder balls 118 and 116. In embodiments, the solder balls 116 that are within the molding compound 120 may allow ready thermal conductivity. In embodiments, the solder balls 116 may form TMV structures.

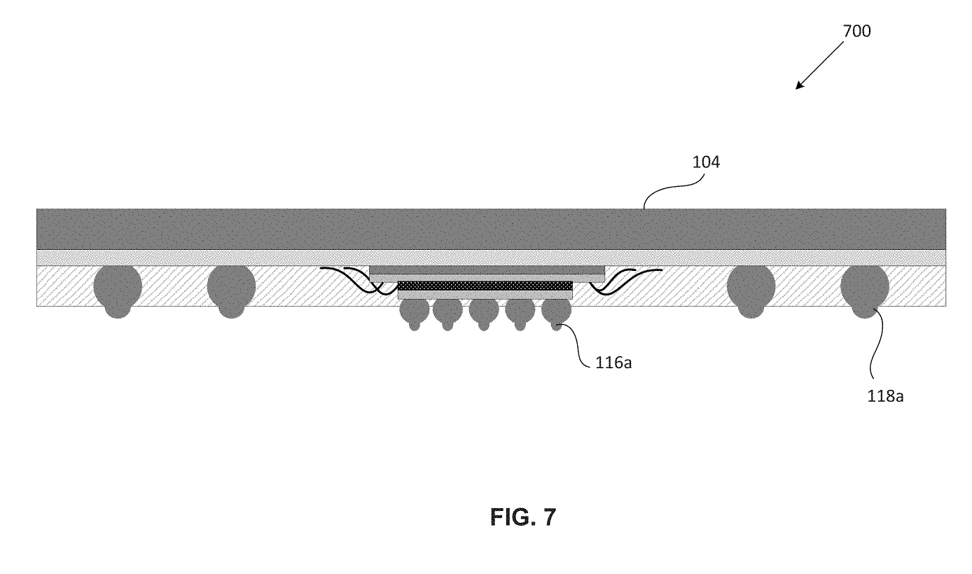

FIG. 7 illustrates a package assembly 700 that shows an additional mound of solder 116 a, 118 a added to the portion of the solder balls 116, 118 exposed by the grinding process shown in FIG. 6. In addition, the carrier layer 104 has been removed. In embodiments, this may be done through a grinding or etching process. In embodiments, package assembly 700 may comprise an embodiment in which a heat spreader may be used in combination with through mold vias that may be subsequently bonded to a PCB. These embodiments may provide ready thermal conductivity to the PCB.

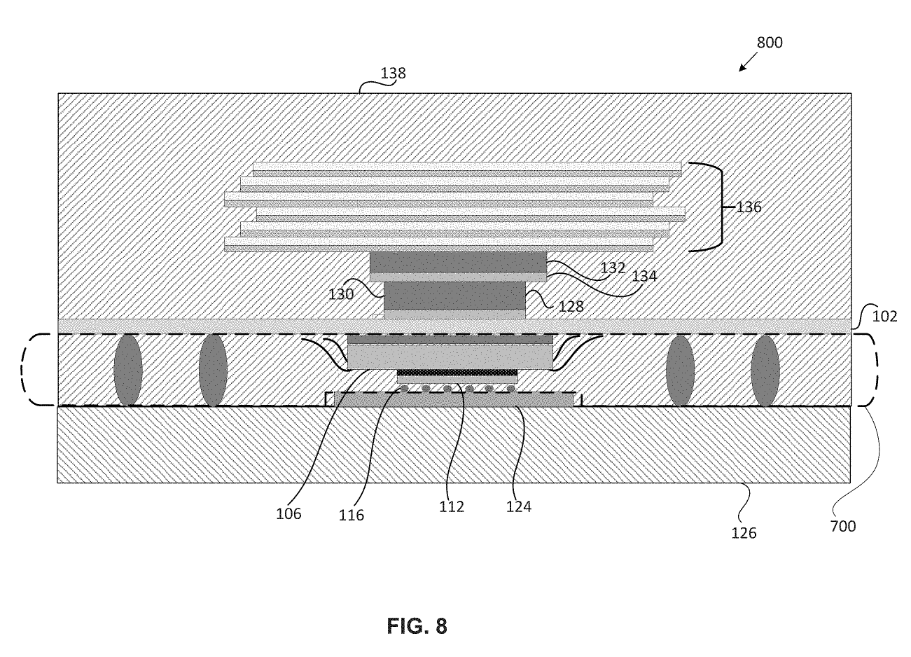

FIG. 8 illustrates a package assembly 800 that includes the package assembly 700 with additional components included. In embodiments, these additional components may include a metal pad 124 that may be coupled to a PCB 126. The metal pad 124 may be thermally coupled to the one or more solder balls 116. In embodiments, this provides a thermal path from the processor 106 through the heat spreader 112, through solder balls 116 and through to the metal pad 124. In embodiments, the metal pad 124 may not be used and instead the package assembly 700 may be directly mounted to the PCB 126.

On the side of the substrate 102 opposite the processor 106, the package assembly 800 may include a glass spacer 128. In embodiments, the glass spacer 128 may be made of any other material having poor thermal conductivity. The glass spacer 128 may be coupled to the substrate 102 by an adhesive 130 coupled to the glass spacer 128 on the opposite side of substrate 102 may be a DRAM 132. In embodiments, the DRAM 132 may be coupled to the glass spacer 128 by an adhesive 134. The DRAM 132 may be coupled to a NAND stack 136. The glass spacer, DRAM, and NAND stack may be embedded in a molding 138.

In embodiments, most of the heat generated from the processor 106 may flow in the direction of the metal plate 124, some of the heat may flow toward the DRAM 132. The glass spacer 128 may serve as a thermal barrier to prevent the DRAM 132 from overheating and failing.

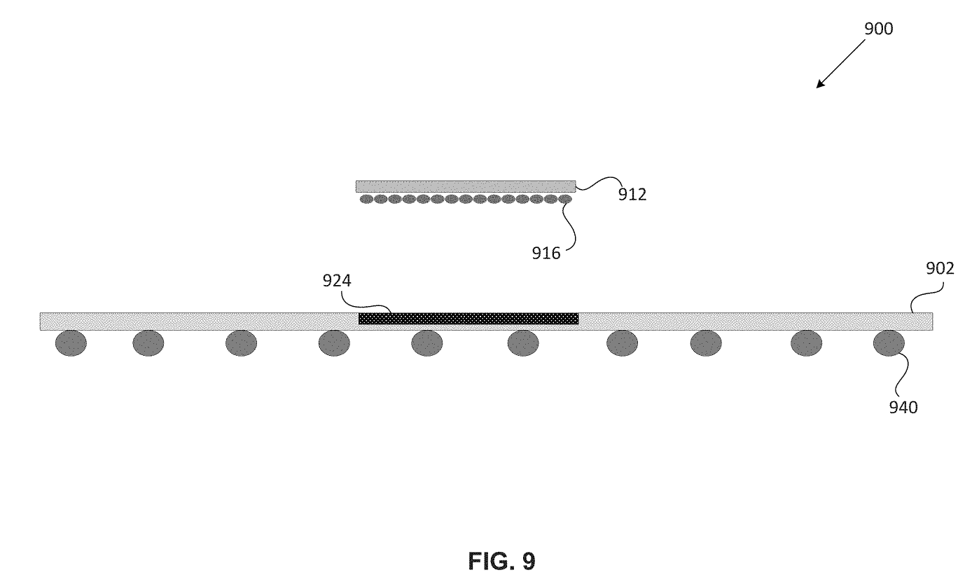

FIG. 9 illustrates an alternative embodiment of a package assembly 900 that shows a heat spreader 912, which in embodiments may be a copper slug, with solder balls 916 attached to one side of the heat spreader 912. Package assembly 900 also shows a substrate 902 with a metal pad 924 that is coupled to the substrate 902. In embodiments, the metal pad 924 may be recessed into the substrate 902. In embodiments the substrate 902 may be a PCB. Solder balls 940 may be attached to the substrate 902 on the side opposite the metal pad 924.

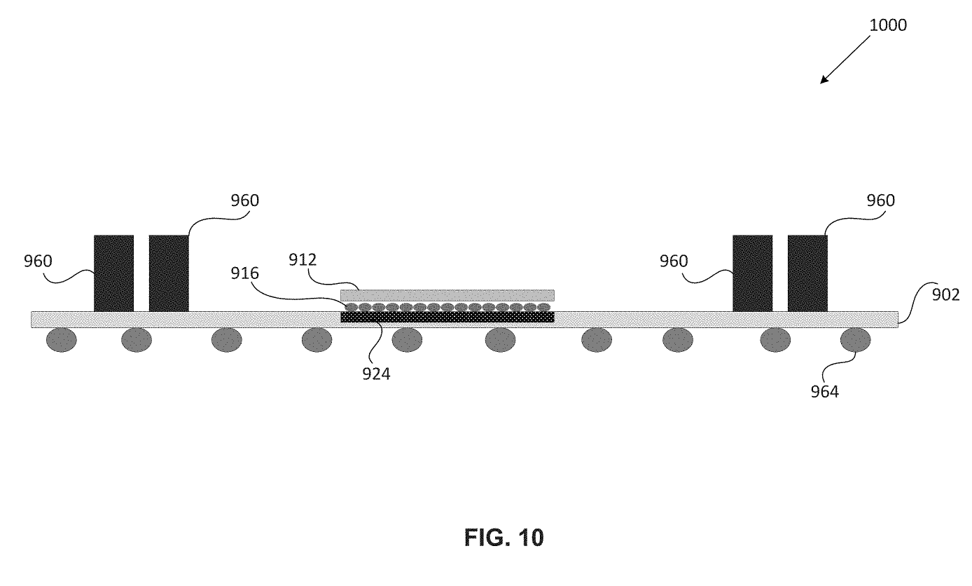

FIG. 10 illustrates a package assembly 1000 where the heat spreader 912 and the solder balls 916 are attached to the metal pad 924. In embodiments, the heat spreader 912 and solder balls 916 may be reflowed onto the substrate 902. The other components that may be surface mounted onto the substrate 902, for example passive devices 960 may be attached. In embodiments solder balls 964 may be coupled to substrate 902 on a side opposite the metal pad 924.

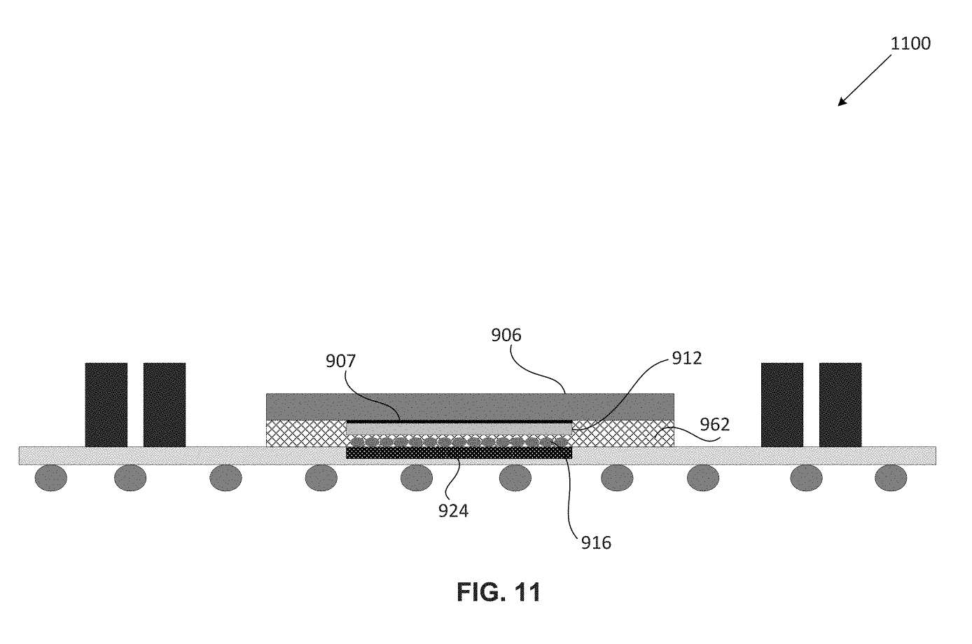

FIG. 11 illustrates a package assembly 1100 in which a processor 906 may be coupled to the heat spreader 912. In embodiments, this coupling may include thermal coupling and electrical coupling. In embodiments, a die attach film (DAF) 907 may be used to facilitate the attachment of the processor 906 to the heat spreader 912. In embodiments, the processor 906 attach process may minimize the adhesive layer between the processor 906 and the heat spreader 912, which may result in lower thermal resistance between the processor 906 and the spreader 912. In embodiments, the processor 906 may be an ASIC, or a may be a stack of processors.

In embodiments, molding 962 may be applied underneath or partially underneath the processor 906 and surrounding or partially surrounding the heat spreader 912, solder balls 916, and/or metal pad 924. Applying the molding 962 around the solder balls 916 may result in TMVs filled with solder material with thermally conductive properties.

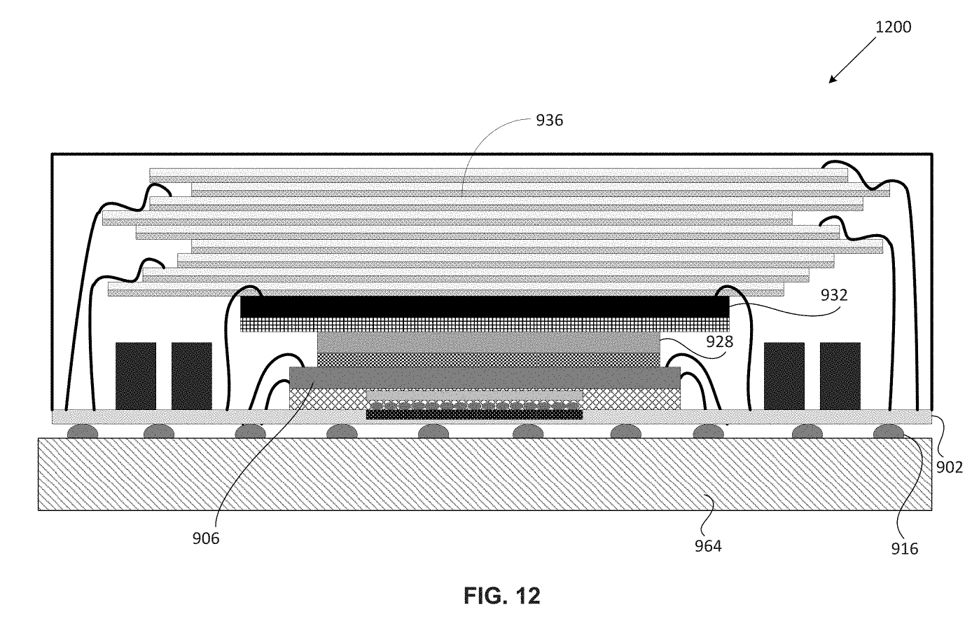

FIG. 12 illustrates a package-in-package assembly 1200 that may include the package assembly 1100 including additional components. In embodiments, substrate 902 may be connected to PCB 964 by solder balls 916. In embodiments, a glass spacer 928 may create a thermal barrier between the processor 906 and DRAM 932, which may be coupled to NAND stack 936. In these embodiments, the majority of the heat generated by processor 906 may flow down into substrate 902, and less of this generated heat flow upward toward DRAM 932. In this way, the DRAM 932 may continue to operate within thermal tolerances even though the processor 906 is in close proximity to the DRAM 932.

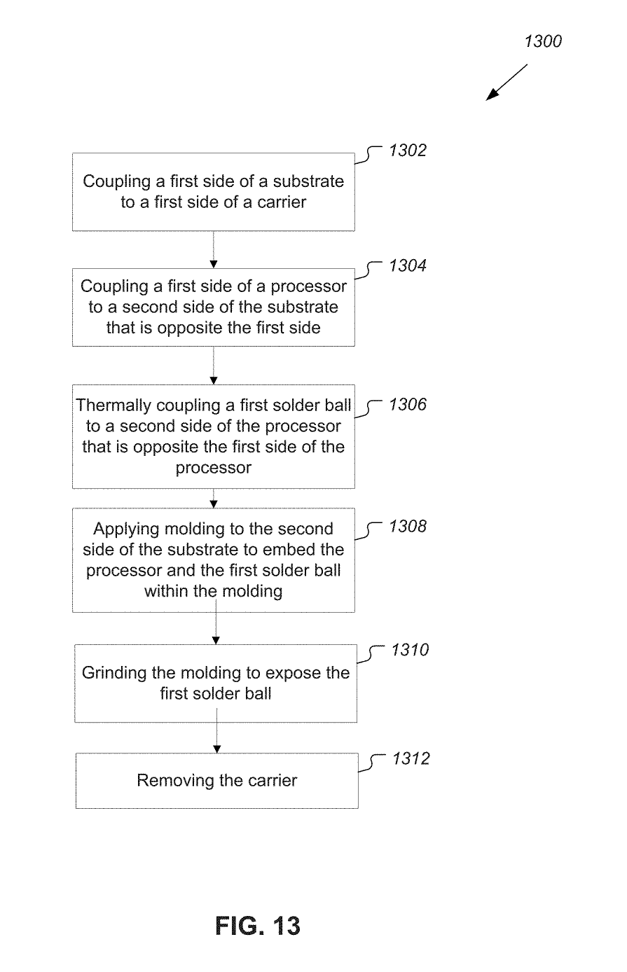

FIG. 13 illustrates an example of a process 1300 for manufacturing a package assembly, such as package assembly 700 of FIG. 7 or portions of the package assembly 800 as shown in FIG. 8, in accordance with embodiments.

At block 1302, the process may include coupling a first side of the substrate to a first side of a carrier. The substrate may be similar to substrate 102 and the carrier may be similar to carrier 104 of FIG. 1. In embodiments, the substrate 102 may be a PCB, or may be an RDL.

At block 1304 the process may include coupling a first side of a processor to a second side of the substrate that is opposite the first side. In embodiments, the processor may be similar to processor 106 that is coupled to substrate 102 on a side opposite that carrier 104, of FIG. 1

At block 1306, the process may include thermally coupling a first solder ball to a second side of the processor that is opposite the first side of the processor. In embodiments, a solder ball 116 may be thermally coupled to processor 106 as shown in FIG. 3. In embodiments, the thermal coupling may include thermal coupling to a heat spreader 112 that may then be thermally coupled to processor 106. In embodiments, the heat spreader 112 may be thermally coupled to the processor 106 using a TIM 114 as shown in FIG. 3.

At block 1308, the process may include applying molding to the second side of the substrate to embed the processor in the first solder ball within the molding. In embodiments, this may include molding 120 of FIG. 5.

At block 1310, the process may include grinding the molding to expose the first solder ball. In embodiments, the grinding may remove the material and area 122 to expose portions of a solder ball 116 thermally coupled to the processor 106, and also exposing solder balls 118 coupled to substrate 102 as shown in FIG. 6.

At block 1312, the process may include removing the carrier. In embodiments, the carrier 104 of FIG. 7 may be removed. In embodiments, carrier 104 may be removed through grinding.

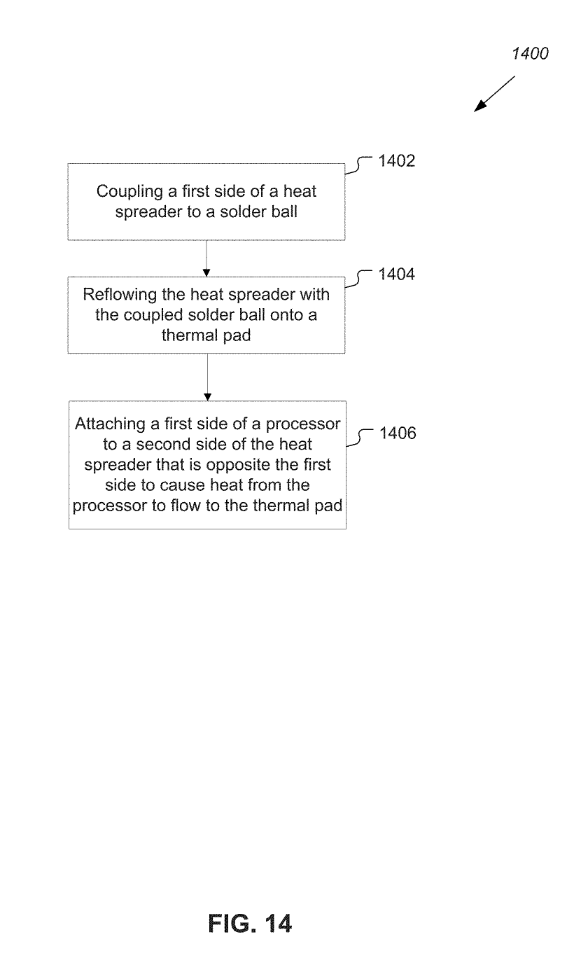

FIG. 14 illustrates an example of a process for manufacturing a package assembly, such as package assembly 1100 as shown in FIG. 11 or portions of package assembly 1200 as shown in FIG. 12, in accordance with embodiments.

At block 1402, the process may include coupling a first side of the heat spreader to a solder ball. In embodiments, the heat spreader may be similar to heat spreader 912, and the solder ball may be similar to one of the solder balls 916 of FIG. 9.

At block 1404, the process may include reflowing the heat spreader with the coupled solder ball onto a thermal pad. In embodiments, the thermal pad may be similar to the metal pad 924 of FIG. 10. In embodiments, the result of the reflowing may be shown by the coupling of the heat spreader 912, solder balls 916, and metal pad 924 of FIG. 10.

At block 1406, the process may include attaching a first side of a processor to a second side of the heat spreader that is opposite the first side to cause heat from the processor to flow to the thermal pad. In embodiments, the processor may be the processor 906 and the heat spreader may be the heat spreader 912 of FIG. 11.

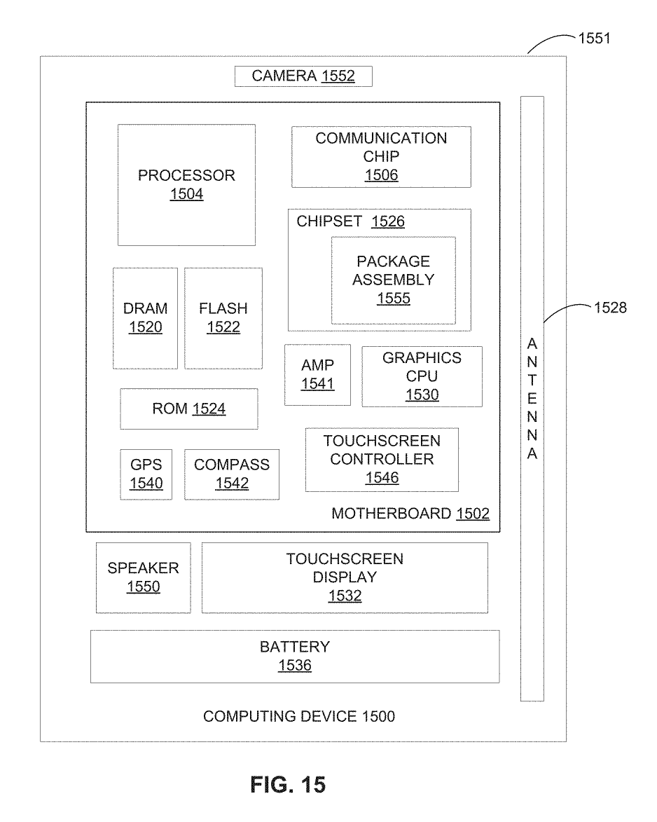

FIG. 15 schematically illustrates a computing device, in accordance with embodiments. Embodiments of the present disclosure may be implemented into a system using any suitable hardware and/or software to configure as desired. The computing device 1500 may house a board such as motherboard 1502 (i.e. housing 1551). The motherboard 1502 may include a number of components, including but not limited to a processor 1504 and at least one communication chip 1506. The processor 1504 may be physically and electrically coupled to the motherboard 1502. In some implementations, the at least one communication chip 1506 may also be physically and electrically coupled to the motherboard 1502. In further implementations, the communication chip 1506 may be part of the processor 1504.

Depending on its applications, computing device 1500 may include other components that may or may not be physically and electrically coupled to the motherboard 1502. These other components may include, but are not limited to, volatile memory (e.g., DRAM) 1520, non-volatile memory (e.g., ROM) 1524, flash memory 1522, a graphics processor 1530, a digital signal processor (not shown), a crypto processor (not shown), a chipset 1526, an antenna 1528, a display (not shown), a touchscreen display 1532, a touchscreen controller 1546, a battery 1536, an audio codec (not shown), a video codec (not shown), a power amplifier 1541, a global positioning system (GPS) device 1540, a compass 1542, an accelerometer (not shown), a gyroscope (not shown), a speaker 1550, a camera 1552, and a mass storage device (such as hard disk drive, compact disk (CD), digital versatile disk (DVD), and so forth) (not shown). Further components, not shown in FIG. 3, may include a microphone, a filter, an oscillator, a pressure sensor, or an RFID chip. In embodiments, one or more of the package assembly components 1555 may be a package assembly such as package assembly 100 shown in FIG. 1.

The communication chip 1506 may enable wireless communications for the transfer of data to and from the computing device 1500. The term “wireless” and its derivatives may be used to describe circuits, devices, systems, processes, techniques, communications channels, etc., that may communicate data through the use of modulated electromagnetic radiation through a non-solid medium. The term does not imply that the associated devices do not contain any wires, although in some embodiments they might not. The communication chip 1506 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 1506 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1506 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1506 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 1506 may operate in accordance with other wireless protocols in other embodiments.

The computing device 1500 may include a plurality of communication chips 1506. For instance, a first communication chip 1506 may be dedicated to shorter range wireless communications such as Wi-Fi and Bluetooth and a second communication chip 1506 may be dedicated to longer range wireless communications such as GPS, EDGE, GPRS, CDMA, WiMAX, LTE, Ev-DO, and others.

The processor 1504 of the computing device 1500 may include a die in a package assembly such as, for example, one of package assemblies 700, 800, 1100, 1200, or any other package assembly using thermal coupling with through mold vias as described herein. The term “processor” may refer to any device or portion of a device that processes electronic data from registers and/or memory to transform that electronic data into other electronic data that may be stored in registers and/or memory.

In various implementations, the computing device 1500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, a solid-state hard drive, an entertainment control unit, a digital camera, a portable music player, or a digital video recorder. In further implementations, the computing device 1500 may be any other electronic device that processes data, for example an all-in-one device such as an all-in-one fax or printing device.

The following paragraphs describe examples of various embodiments.

Example 1 may be a package comprising: a substrate, having a first side and a second side opposite the first side; a processor having a first side and a second side opposite the first side, the first side of the processor coupled to the first side of the substrate; one or more solder balls; wherein the one or more solder balls are thermally coupled to the second side of the processor; wherein the one or more solder balls are embedded within a molding; and wherein the one or more solder balls extend from a first side of the molding to a second side of the molding opposite the first side of the molding.

Example 2 may include the package of Example 1, wherein the one or more solder balls form through mold vias, TMVs, within the molding.

Example 3 may include the package of Example 1, further comprising an adhesive between the first side of the processor and the first side of the substrate.

Example 4 may include the package of Example 1, further comprising a heat spreader having a first side and a second side opposite the first side, the heat spreader positioned between the second side of the processor and the one or more solder balls, wherein the first side of the heat spreader is thermally coupled to the second side of the processor and the second side of the heat spreader is thermally coupled to the one or more solder balls.

Example 5 may include the package of Example 4, wherein the heat spreader is a copper slug.

Example 6 may include the package of any Examples 4-5, further comprising a thermal interface material, TIM, having a first side and a second side opposite the first side, the TIM positioned between the second side of the processor and the first side of the heat spreader, wherein the first side of the TIM is thermally coupled to the second side of the processor and the second side of the TIM is thermally coupled to the first side of the heat spreader.

Example 7 may include the package of any Examples 1-5, wherein the processor is a stack of processors.

Example 8 may include the package of any Examples 1-5, wherein the processor is an application specific integrated circuit, ASIC.

Example 9 may include the package of any Examples 1-5, wherein the substrate is a redistribution layer, RDL.

Example 10 may include the package of any Examples 1-5, further comprising a glass spacer having a first side and a second side opposite the first side, wherein the second side of the substrate is coupled to the first side of the glass spacer, and wherein the glass spacer is to thermally insulate the processor.

Example 11 may include the package of Example 10, further comprising an adhesive between the second side of the substrate and the first side of the glass spacer.

Example 12 may include the package of Example 10, wherein the second side of the glass spacer is coupled to a dynamic random access memory, DRAM, chip or a negative-AND gate, NAND, stack.

Example 13 may include the package of any Examples 1-5, wherein the second side of the one or more solder balls are thermally coupled to a metal pad of a printed circuit board, PCB, wherein the metal pad provides a thermal path for heat generated by the processor.

Example 14 may be a method for creating a package, comprising: coupling a first side of a substrate to a first side of a carrier; coupling a first side of a processor to a second side of the substrate that is opposite the first side; thermally coupling a first solder ball to a second side of the processor that is opposite the first side of the processor; applying molding to the second side of the substrate to embed the processor and the first solder ball within the molding; and grinding the molding to expose the first solder ball.

Example 15 may include the method of Example 14, further comprising coupling a second solder ball to the second side of the substrate; and wherein grinding the molding is further to expose the second solder ball.

Example 16 may include the method of Example 15, further comprising applying a solder mound to the exposed second solder ball.

Example 17 may include the method of Example 14, wherein the substrate is a redistribution layer, RDL.

Example 18 may include the method of Example 14, further comprising inserting a heat spreader between the processor and the first solder ball, wherein a first side of the heat spreader is coupled to a second side of the processor that is opposite the first side, and a second side of the heat spreader that is opposite the first side is coupled to the first solder ball.

Example 19 may include the method of Example 18, wherein the heat spreader is a copper slug.

Example 20 may include the method of Example 18, further comprising a thermal interface material, TIM, between the second side of the processor and the first side of the heat spreader.

Example 21 may include the method of Example 14, further comprising attaching the first side of the processor to the second side of the substrate using an adhesive film.

Example 22 may include the method of Example 14, wherein the processor is a stack of processors.

Example 23 may include the method of Example 14, wherein the processor is an application specific integrated circuit, ASIC.

Example 24 may be a method for creating a package, comprising: coupling a first side of a heat spreader to a solder ball; reflowing the heat spreader with the coupled solder ball onto a thermal pad; attaching a first side of a processor to a second side of the heat spreader that is opposite the first side to cause heat from the processor to flow to the thermal pad.

Example 25 may include the method of Example 24, wherein attaching a first side of the processor to the heat spreader further comprises using film over wire, FOW, adhesive.

Example 26 may include the method of Example 24, wherein the thermal pad is embedded on a substrate.

Example 27 may include the method of Example 26, wherein the substrate is a redistribution layer, RDL, or a printed circuit board, PCB.

Example 28 may include the method of Example 24, wherein the heat spreader is a copper heat slug.

Example 29 may be a system with a package assembly, the system comprising: a circuit board; a package assembly coupled with the circuit board, the package assembly comprising: a substrate, having a first side and a second side opposite the first side; a processor having a first side and a second side opposite the first side, the first side of the processor coupled to the first side of the substrate; one or more solder balls; wherein the one or more solder balls are thermally coupled to the second side of the processor; wherein the one or more solder balls are embedded within a molding; and wherein the one or more solder balls extend from the first side of the molding to the second side of the molding opposite the first side of the molding.

Example 30 may include the system of Example 29, wherein the one or more solder balls form through mold vias, TMVs, within the molding.

Example 31 may include the system of Example 30, the package assembly further comprising an adhesive between the first side of the processor in the first side of the substrate.

Example 32 may include the system of Example 30, the package assembly further comprising a heat spreader having a first side and a second side opposite the first side, the heat spreader positioned between the second side of the processor and the one or more solder balls, wherein the first side of the heat spreader is thermally coupled to the second side of the processor and the second side of the heat spreader is thermally coupled to the one or more solder balls.

Example 33 may include the system of any Examples 31-32, the package assembly further comprising a thermal interface material, TIM, having a first side and a second side opposite the first side, the TIM positioned between the second side of the processor and the first side of the heat spreader, wherein the first side of the TIM is thermally coupled to the second side of the processor and the second side of the TIM is thermally coupled to the first side of the heat spreader.

Example 34 may include the system of any Examples 30-33, wherein the processor is a stack of processors.

Example 35 may include the system of any Examples 30-33, wherein the processor is an application specific integrated circuit, ASIC.

Example 36 may include the system of any Examples 30-33, wherein the substrate is a redistribution layer, RDL.

Example 37 may include the system of any Examples 30-33, the package assembly further comprising a glass spacer having a first side and a second side opposite the first side, wherein the second side of the substrate is coupled to the first side of the glass spacer, and wherein the glass spacer is to thermally insulate the processor.

Example 38 may include the system of Example 37, the package assembly further comprising an adhesive between the second side of the substrate and the first side of the glass spacer.

Example 39 may include the system of Example 38, wherein the second side of the glass spacer is coupled to a dynamic random access memory, DRAM, chip or a negative-AND gate, NAND, stack.

Example 40 may include the system of any Examples 30-33, wherein the second side of the one or more solder balls are thermally coupled to a metal pad of a printed circuit board, PCB, wherein the metal pad provides a thermal path for heat generated by the processor.

Example 41 may be a device comprising: means for coupling a first side of a substrate to a first side of a carrier; means for coupling a first side of a processor to a second side of the substrate that is opposite the first side; means for thermally coupling a first solder ball to a second side of the processor that is opposite the first side of the processor; means for applying molding to the second side of the substrate to embed the processor and the first solder ball within the molding; and means for grinding the molding to expose the first solder ball.

Example 42 may include the device of Example 41, further comprising means for coupling a second solder ball to the second side of the substrate; and wherein means for grinding the molding is further to expose the second solder ball.

Example 43 may include the device of Example 42, further comprising applying a solder mound to the exposed second solder ball.

Example 44 may include the device of Example 41, wherein the substrate is a redistribution layer, RDL.

Example 45 may include the device of any Examples 41-44, further comprising means for inserting a heat spreader between the processor and the first solder ball, wherein a first side of the heat spreader is coupled to a second side of the processor that is opposite the first side, and a second side of the heat spreader that is opposite the first side is coupled to the first solder ball.

Example 46 may include the device of Example 45, wherein the heat spreader is a copper slug.

Example 47 may include the device of Example 45, further comprising a thermal interface material, TIM, between the second side of the processor and the first side of the heat spreader.

Example 48 may include the device of Example 41, further comprising means for attaching the first side of the processor to the second side of the substrate using an adhesive film.

Example 49 may include the device of any Examples 41-44, wherein the processor is a stack of processors.

Example 50 may include the device of any Examples 41-44, wherein the processor is an application specific integrated circuit, ASIC.

Example 51 may be a device comprising: means for coupling a first side of a heat spreader to a solder ball; means for reflowing the heat spreader with the coupled solder ball onto a thermal pad; means for attaching a first side of a processor to a second side of the heat spreader that is opposite the first side to cause heat from the processor to flow to the thermal pad.

Example 52 may include the device of Example 51, wherein means for attaching a first side of the processor to the heat spreader further comprises using film over wire, FOW, adhesive.

Example 53 may include the device of Example 51, wherein the thermal pad is embedded on a substrate.

Example 54 may include the device of Example 53, wherein the substrate is a redistribution layer, RDL, or a printed circuit board, PCB.

Example 55 may include the device of any Examples 51-53, wherein the heat spreader is a copper heat slug.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

1. A package comprising:
a substrate, having a first side and a second side opposite the first side;
a processor having a first side and a second side opposite the first side, the first side of the processor coupled to the first side of the substrate;
one or more solder balls, wherein the one or more solder balls are thermally coupled to the second side of the processor, wherein the one or more solder balls are embedded within a molding, wherein the one or more solder balls extend from a first side of the molding to a second side of the molding opposite the first side of the molding;
a glass spacer having a first side and a second side opposite the first side, wherein the second side of the substrate is coupled to the first side of the glass spacer; and
a dynamic random access memory (DRAM) chip or a negative-AND gate (NAND) stack coupled to the second side of the glass spacer, wherein the DRAM chip or NAND stack is thermally isolated from the processor.

2. The package of claim 1, wherein the one or more solder balls form through mold vias, TMVs, within the molding.

3. The package of claim 1, further comprising an adhesive between the first side of the processor and the first side of the substrate.

4. The package of claim 1, further comprising a heat spreader having a first side and a second side opposite the first side, the heat spreader positioned between the second side of the processor and the one or more solder balls, wherein the first side of the heat spreader is thermally coupled to the second side of the processor and the second side of the heat spreader is thermally coupled to the one or more solder balls.

5. The package of claim 3, further comprising a thermal interface material, TIM, having a first side and a second side opposite the first side, the TIM positioned between the second side of the processor and the first side of the heat spreader, wherein the first side of the TIM is thermally coupled to the second side of the processor and the second side of the TIM is thermally coupled to the first side of the heat spreader.

6. The package of claim 1, wherein the processor is a stack of processors.

7. The package of claim 1, wherein the processor is an application specific integrated circuit, ASIC.

8. The package of claim 1, wherein the substrate is a redistribution layer, RDL.

9. (canceled)

10. The package of claim 1, further comprising an adhesive between the second side of the substrate and the first side of the glass spacer.

11. (canceled)

12. The package of claim 1, wherein a second side of the one or more solder balls are thermally coupled to a metal pad of a printed circuit board, PCB, wherein the metal pad provides a thermal path for heat generated by the processor.

13. A method for creating a package, comprising:
coupling a first side of a substrate to a first side of a carrier;
coupling a first side of a processor to a second side of the substrate that is opposite the first side;
thermally coupling a first solder ball to a second side of the processor that is opposite the first side of the processor;
applying molding to the second side of the substrate to embed the processor and the first solder ball within the molding; and
grinding the molding to expose the first solder ball.

14. The method of claim 13, further comprising coupling a second solder ball to the second side of the substrate; and
wherein grinding the molding is further to expose the second solder ball.

15. The method of claim 14, further comprising applying a solder mound to the exposed second solder ball.

16. The method of claim 13, wherein the substrate is a redistribution layer, RDL.

17. The method of claim 13, further comprising inserting a heat spreader between the processor and the first solder ball, wherein a first side of the heat spreader is coupled to a second side of the processor that is opposite the first side, and a second side of the heat spreader that is opposite the first side is coupled to the first solder ball.

18. The method of claim 17, wherein the heat spreader is a copper slug.

19. The method of claim 17, further comprising a thermal interface material, TIM, between the second side of the processor and the first side of the heat spreader.

20. The method of claim 13, further comprising attaching the first side of the processor to the second side of the substrate using an adhesive film.

21. The method of claim 13, wherein the processor is a stack of processors.

22. The method of claim 13, wherein the processor is an application specific integrated circuit, ASIC.

23. A method for creating a package, comprising:
coupling a first side of a heat spreader to a solder ball;
reflowing the heat spreader with the coupled solder ball onto a thermal pad;
attaching a first side of a processor to a second side of the heat spreader that is opposite the first side to cause heat from the processor to flow to the thermal pad.

24. The method of claim 23, wherein attaching a first side of the processor to the heat spreader further comprises using film over wire, FOW, adhesive.

25. The method of claim 23, wherein the thermal pad is embedded on a substrate.
